(19) United States
(12) Patent Application Publication
(10) Pub. No.: US 2026/0280144 A1
(43) Pub. Date: Sep. 17, 2026

(54) METHOD TO DEVELOP A RADIO FREQUENCY COMMUNICATIONS DEVICE WITH IMPROVED PERFORMANCE AND A DEVICE DEVELOPED ACORDING TO SAID METHOD

(71) Applicant: SkyMirr, Inc., Melbourne, FL (US)

(72) Inventor: Youngmin JO, Melbourne, FL (US)

(21) Appl. No.: 19/569,276

(22) Filed: Mar. 17, 2026

Related U.S. Application Data
(60) Provisional application No. 63/772,903, filed on Mar. 17, 2025.

(51) Int. Cl. H01Q 21/06; G01R 29/10; H01Q 1/24; H01Q 1/52

(52) U.S. Cl. CPC H01Q 21/061; G01R 29/10; H01Q 1/24; H01Q 1/52

(57) ABSTRACT

A method for designing a communications device comprising an antenna system to achieve a predetermined radiation performance. After identifying a frequency, a frequency band, and frequency bands for the communications device, determining a number of antennas, a physical placement for each antenna, and designing antenna elements for each antenna. Then testing the antenna system relative to the predetermined radiation performance. If the predetermined radiation performance is not achieved, modifying one or more antenna elements. If the predetermined radiation performance is achieved, designing an enclosure for the antenna system and incorporating the antenna system into the enclosure. Testing the antenna system within the enclosure and if the predetermined radiation performance is achieved the design is complete. If the predetermined radiation performance is not achieved modifying one or more elements of the enclosure and retesting the antenna system.

### CROSS REFERENCE TO RELATED APPLICATIONS

The present application claims priority under 35 U.S.C. 119(e) to the provisional patent application filed on Mar. 17, 2025 and assigned application No. 63/772,903 (Attorney Docket 16514-015P). The contents of that application are incorporated herein.

### FIELD OF THE INVENTION

This invention relates to methods (and devices designed according to said methods) for designing radio frequency (RF) communications devices that employ one or more antennas for transmitting and receiving the RF signals, and more specifically, to methods (and devices designed according to said methods) that provide improved RF antenna performance.

### BACKGROUND OF THE INVENTION

A prior art flowchart 10 of FIG. 1 depicts the typical steps associated with designing a radio frequency communications device, one type specifically referred to as a consumer premises equipment (CPE) device. The enclosure is typically designed first to satisfy a desired appearance that is suitable for placement of the CPE in a home or business environment. The required CPE components, especially the antennas, are then shoe-horned into the existing CPE interior space, often resulting in component operation causing significant interference with antenna operation and therefore unacceptable antenna performance. If the antenna performance is unacceptable then the performance of the CPE device will similarly be unsuccessful.

As can be seen from FIG. 1, after the enclosure design is complete, components are next selected and the requisite printed circuit board is designed to accommodate those components. Cables and connectors are then designed and installed, typically without regard to the eventual antenna locations. The eventual result is typically insufficient space for an antenna and thereby antenna performance falling below some desired objective.

Software development is the next step.

Finally, the antennas are designed and installed in the already-designed enclosure at step 12. At decision step 13 the CPE device is tested to determines whether the performance is satisfactory. If the performance is not satisfactory processing moves to a step 14 where the hardware software and antenna elements are debugged and then redesigned as necessary to pass the performance test. Normally several design iterations/debugging cycles are required due to insufficient radiation performance, which ironically is the most important factor associated with performance of the CPE device. Finally, the product is certified and then mass produced.

It is well known that antenna performance is the dominating factor in the performance of any wireless communications device. This can be seen especially seen from a wireless link budget calculation as shown below.

$$Received power ( dBm ) = transmitted power ( dBm ) + transmitter antenna gain ( dBi ) - path loss ( dB ) - receiver losses ( dB ) + receiver antenna gain ( dBi ) .$$

As described in the FIG. 1 design example, antenna placement and size are typically ignored in the wireless communications device development and are frequently the last components to be designed, resulting in poor antenna and CPE performance that is caused by insufficient antenna space, interference from proximate components, and antenna placement close to noise sources.

### BRIEF DESCRIPTION OF THE DRAWINGS

The present invention can be more easily understood and the advantages and uses thereof more readily apparent when the detailed description of the present invention is read in conjunction with the figures wherein:

FIG. 1 illustrates a prior art method for designing a communications device.

FIG. 2 illustrates a method for designing a communications device according to the teachings of the present invention.

FIG. 3 illustrates a communications device designed according to the methods of the present invention.

FIG. 4 illustrates frequencies associated with the communications device of FIG. 3.

FIG. 5 illustrates a exemplary dipole antenna for use with the communications device designed according to the teachings of the present invention.

FIG. 6 illustrates a computer and related elements for designing the communications device of the present invention.

In accordance with common practice, the various described features are not drawn to scale, but are drawn to emphasize specific features relevant to the invention. Like reference characters denote like elements throughout the figures and text.

### DETAILED DESCRIPTION OF THE INVENTION

Unless defined otherwise, all technical and scientific terms used herein have the same meaning as commonly understood by one of ordinary skill in the art to which this invention pertains. Although any methods and materials similar or equivalent to those described herein can be used in the practice or testing of the invention, the preferred methods and materials are now described. All publications mentioned herein are incorporated herein by reference.

The terms “about” or “approximately” as used herein when referring to a measurable value such as a parameter, an amount, a temporal duration, and the like, are meant to encompass variations of and from the specified value, such as variations of +/−10% or less, +/−5% or less, +/−1% or less, and +/−0.1% or less of and from the specified value, insofar such variations are appropriate to perform in the disclosed invention. It is to be understood that the value to which the modifier “about” or “approximately” refers is itself also specifically, and preferably, disclosed.

Reference throughout this specification to “one embodiment”, “an embodiment,” “an example embodiment,” means that a particular feature, structure, or characteristic described in connection with the embodiment is included in at least one embodiment of the present invention. Thus, appearances of the phrases “in one embodiment,” “in an embodiment,” or “an example embodiment” in various places throughout this specification are not necessarily all referring to the same embodiment but may.

Furthermore, the features, structures or characteristics may be combined in any suitable manner, as would be apparent to a person skilled in the art of this disclosure, in one or more embodiments. Furthermore, while some embodiments described herein include some, but not other features included in other embodiments, combinations of features of different embodiments are meant to be within the scope of the invention. For example, in the appended claims, any of the claimed embodiments can be used in any combination.

The shape and dimensions of the antennas described herein and shown in the various figures is merely representative of the many different antenna shapes and sizes that can benefit from the teachings of the present invention.

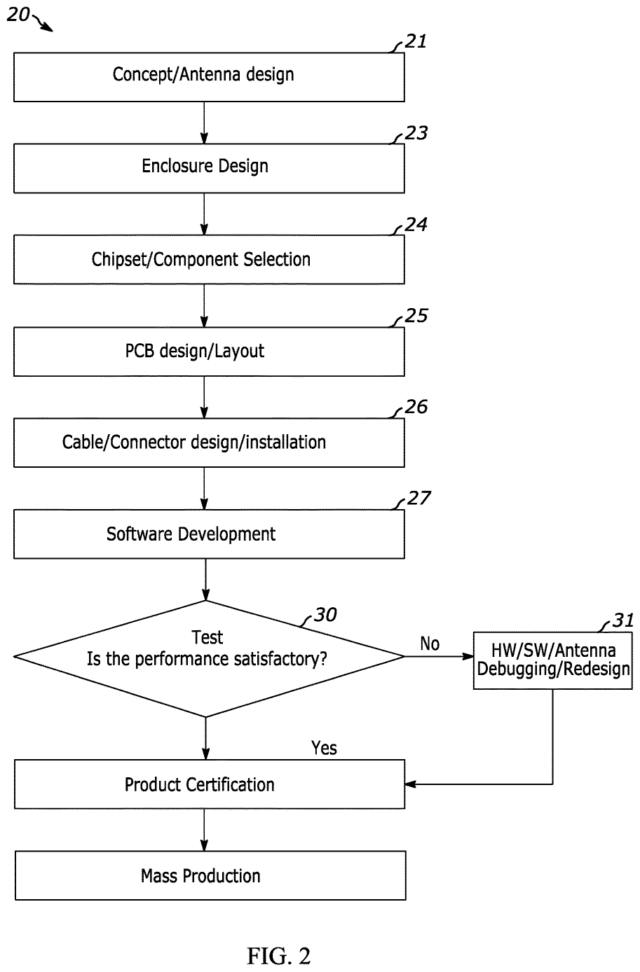

FIG. 2 illustrates a design process associated with the present invention, wherein the antenna concepts and designs are executed at a step 21; the first step in a flowchart 20 identifying novel and nonobvious CPE design process steps. Moving the antenna design step to the beginning of the design process improves antenna performance by ensuring that the antennas are carefully and adequately designed for the intended application and that components that might physically and electrically interfere with antenna performance are designed with the antenna design parameters and location in place.

After the antenna has been designed and tested at the step 21, processing moves to a enclosure design step 23, chipset/component selection 24, PCB design and component layout 25, cable/conductor design and installation 26, and development of the operating software at a step 27.

For example, the PCB design at the step 25 should locate the PCB at a maximum distance from the antennas as it is known that signals emitted by the antenna will likely effect performance of the PCB components and signals emitted by the PCB components will likely affect antenna performance.

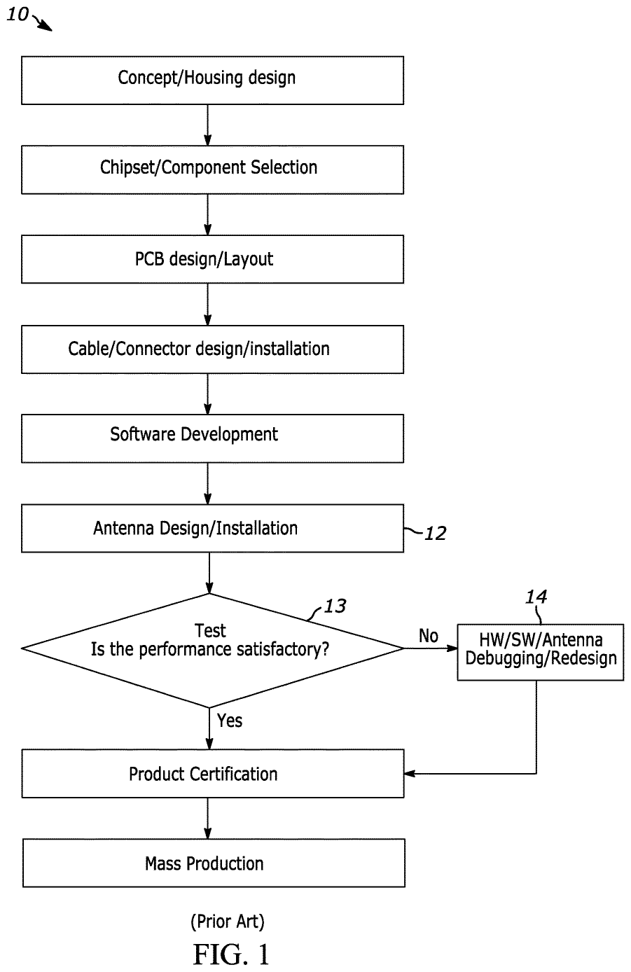

The design flow of FIG. 1 ensures that the antennas will perform as expected, as any degradation in antenna performance must have been caused by one or more of the steps that follow antenna design and testing. This novel and nonobvious design process ensures that fewer design and redesign iterations will be required at steps 30 and 31 (of FIG. 2) to maximize antenna performance.

The communications device enclosure can cause multiple and deleterious effects on operation of the antennas of the communications device. Following are several enclosure characteristics and their effect on antenna performance, i.e., antenna radiation performance.

### Dielectric Loading (Detuning)

When the enclosure is made of plastic, glass, ceramic, or composite, it behaves as a dielectric material around the antenna. This increases the effective permittivity that is seen by the antenna and shifts the antenna's resonant frequency, usually downward. Also, the antenna input impedance changes and the antenna bandwidth can shrink. These effects typically reduce the radiation efficiency of the antenna.

As is known by those skilled in the art, an antenna's resonance depends on wavelength in the surrounding medium. If the enclosure of the communications device increases the effective permittivity, the antenna electrical length increases and the antenna resonance shifts to a lower frequency. Generally, a plastic enclosure or housing has a moderate detuning effect; a high ε glass or ceramic causes stronger detuning. Detuning effects increase with wall thickness.

A metal enclosure (e.g., frame, bezel, chassis, and coating) significantly affects the signal/energy radiated by the antenna. The metal enclosure acts as a shield, reducing the outward radiation, creates parasitic currents, alters the antenna radiation pattern, changes the signal polarization, and may create additional resonant frequencies. The metal enclosure may also act as a radiation reflector if sufficiently close to the radiating antenna, will definitely act as a reflector if placed at a distance of about λ/4 from the antenna, if too close, the housing may short circuit near radiation fields, and may serve as a unintended element of the antenna.

Some housing materials are lossy, resulting in a dielectric loss tangent. Thus, RF energy transmitted and received by the antenna is absorbed as heat, thereby decreasing antenna efficiency and reducing antenna gain. Lossy materials placed near high-field regions (such as feed points, edges of patch antenna, and ends of dipole) are especially problematic.

The enclosure can distort the antenna radiation pattern by blocking radiation in certain directions, thereby creating an asymmetric radiation pattern and introduce unwanted pattern nulls. Also, thicker enclosures and enclosures with variable thickness may distort the far-field radiation pattern (a particular problem at millimeter wave frequencies).

The enclosure modifies the antenna's near-field distribution, which changes current distribution within the antenna, alters the antenna impedance, and modifies mutual coupling between antennas operating in a MIMO system, that is, the enclosure can increase correlation between the MIMO antennas and reduce isolation between them.

Also, it is not advisable to use the device chassis as part of the antenna as this configuration may change the current return paths to the antenna, alter the effective size of the ground plane, and shift the radiation mode structure. Small communications devices are especially sensitive to these problems because the entire device becomes part of the antenna system.

The effect of the enclosure on antenna radiation performance increases as the operating frequency increases. Below 1 GHz the effect is moderate, but from 1-6 GHz and for millimeter waves the effect on the operating frequency is high.

A thicker enclosure material increases a distance between the user's tissue and the device, which reduces the specific absorption rate and the body loading effects on antenna performance. However, a thicker enclosure can disadvantageously increase detuning of the antenna.

Given the significant effects of the enclosure on antenna radiation performance, the present invention teaches designing the antenna separate and apart (and first) from the housing and testing and modifying one or more antenna parameters to achieve the desired antenna performance. Only then is the antenna mated with a enclosure that has been designed with consideration of the issues set forth above. The antenna is tuned within the final enclosure and performance of the antenna is retested to ensure that the enclosure has not degraded radiation performance to an unacceptable level.

To accelerate the finals design process, antenna performance may be first simulated (using HFSS or CST) with the enclosure included in the simulation analysis.

During the simulation process or during live performance testing, matching and tuning circuits are added as required to improve antenna performance. Also, the enclosure thickness can be varied as required to improve antenna performance.

After the antenna performance has been successfully tested within the enclosure, chipset/component are selected, the PCB designed and component layout performed, cables/conductors are designed and installed, and finally the operating software is developed.

As design of the communications device proceeds as set forth above, it is particularly important to avoid the placement of metal or metal objects directly over high-field antenna regions.

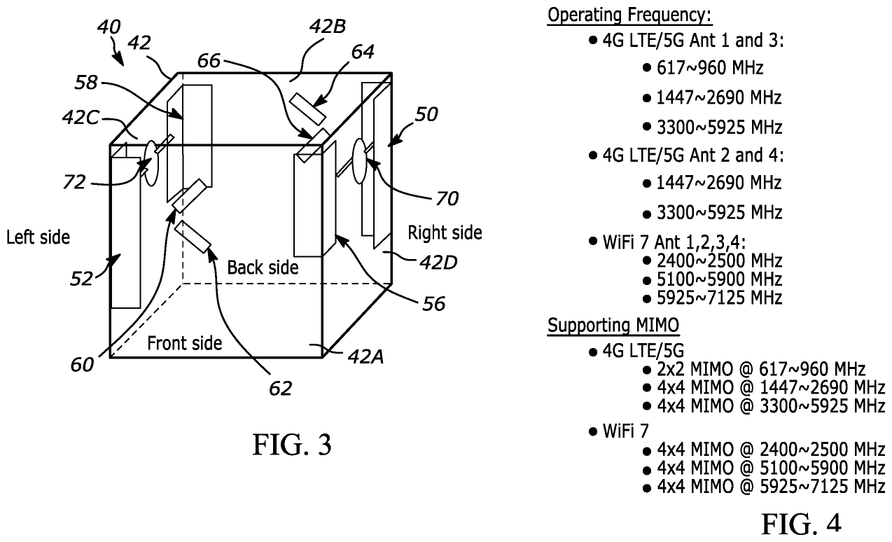

One example of a communications device (in this example the device is sometimes referred to as a customer premises equipment or CPE) with multiple antennas that was designed using the step-by-step methodology of the present invention is illustrated in FIG. 3. Other communications devices can be designed using this methodology, such as an internet of things (IOT) device.

The design methodology for the CPE 40 depicted in FIG. 3 begins with the design and placement of the antennas. The antennas are installed at specific relative locations and decoupled as required, to offer measurably improved performance, when compared with a CPE device wherein the antennas were designed and placed at the end of the CPE design process.

The CPE device 40 comprises a enclosure 42 further comprising a front surface 42A, a back surface 42B, a left side surface 42C, and a right-side surface 42D. The rectangular shape is preferred over a square shape as it provides additional separation between two antennas 52 and 58 installed as a pair on the left side surface 42C relative to two antennas 50 and 56 installed as a pair on the right side 42D. This rectangular arrangement provides sufficient distance between the antenna pairs to avoid interference. Other enclosure shapes can be used so long as the shape offers at least one dimension that is longer than other dimensions, e.g. an oblong oval shape may be suitable, while a square shape is generally not suitable for a CPE device with multiple antennas.

According to one application, the antennas 50 and 52 comprise cellular antennas 50 and 52 (disposed at opposing corners of the enclosure 42) designed for operation according to the 4G LTE and 5G sub 6 cellular standards within the frequency bands of 617-960 MHz, 1447-2690 MHz, and 3300-5925 MHz. “5G sub 6” refers to the use of 5G technology within the frequency spectrum below 6 GHz, which provides an acceptable balance between signal coverage and data speed.

Antennas 56 and 58 comprise cellular antennas 56 and 58 disposed at opposing corners of the CPE enclosure 42. These two antennas are also designated for operation according to the 4G LTE and 5G sub 6 cellular standards within the frequency bands of: 617-960 MHz, 1447-2690 MHz and 3300-5925 MHz.

Although use of a rectangular enclosure to accommodate the cellular antennas 50, 52, 56, and 58 provides sufficient separation to avoid interference between the antenna pair 52/58 and the antenna pair 50/56, generally, when antennas are placed in a proximate relationship (such as the antennas 50 and 56 in the first pair and the antennas 52 and 58 in the second pair) negative mutual coupling occurs between the radiated signals and this phenomenon reduces the radiation performance when both antennas in the pair operate simultaneously, for example, during MIMO operation.

Although any one of the antennas in FIG. 3 can be operated independently of the other antennas, improved performance is realized by operating multiple antennas together in a MIMO network to provide higher data rates with improved signal quality, when compared with a single antenna (SISO), especially in the presence of interference or low signal strength. Supporting electronics elements combine or separate the transmitted and received signals as required. MIMO is a key component of modern wireless technologies, including cellular standards 4G LTE and 5G sub 6, and WiFi standards 5, 6, and 7.

The use of 2×2 MIMO technology increases connection speeds by about 30% over a SISO antenna system. Using 4×4 MIMO technology improves the connection speed by about 70% over a SISO system. These benefits can be realized even when data transmission is congested at the cell tower or at the WiFi router.

But simultaneous antenna operation to accommodate 2×2 or 4×4 MIMO tends to cause the field generated by a first antenna in the pair to negatively affect the field generated by the second antenna in the pair. For example, the radiated signal produced by the antenna 52 generates an electric field at the location of the antenna 58. This electric field can drive surface currents at the antenna 58 and these surface currents can flow in an opposite direction relative to the surface currents generated by the source driving the antenna 58.

If the two antennas are located in proximity (as is the case for the antenna pair 52/58 and similarly for the antenna pair 50/56) the negative coupling is strong and the generated surface currents are significant, thereby causing field/energy cancellation and resulting in a significant performance reduction for the antenna pair.

The negative coupling between proximate antennas can be reduced by simply spacing the antennas at a sufficient distance to minimize the negative coupling. But these spacing requirements mandate a large enclosure, which is undesired in many applications, such as when the antennas are collocated in or are located on a relatively small CPE. However, designing and placing all antennas in the communicating device at the beginning of the CPE design process can minimize the negative coupling.

In situations where the negative coupling continues to present problems, after separating the antennas by the maximum available distance, a radiation decoupling network is required. A coupler (more accurately a decoupler) designed specifically to reduce the negative coupling can be connected to the two interfering antennas. Further details of these couplers, beyond the description presented herein, are provided and claimed in co-owned and co-pending application entitled, MIMO Antenna System to Improve Performance of Mobile Telecommunication Devices, filed on Jan. 6, 2026 and assigned application Ser. No. 19/441,019 (Attorney Docket Number 16514-012US1).

The shape of the CPE enclosure 42 is rectangular (not square) in the x-y plane. This feature provides sufficient spacing between the pair 50 and 56 on right side 42D from the antenna pair 52 and 58 on left side 42C. Thus, the rectangular shape avoids the need for decoupling elements for the antennas separated by the longer dimension of the rectangle.

But decoupling elements are employed for the antennas separated by the shorter dimension of the rectangle at the operating frequency.

The antennas 50 and 56 (and the antennas 52 and 58) are placed at the corners of the CPE enclosure and separated by the shorter dimension of the rectangle. These antenna pairs are sufficiently close to likely cause coupling issues when operating simultaneously, such as during MIMO operation; experimental results will typically substantiate the radiation losses and resulting problems.

To improve MIMO antenna performance, each closely spaced antenna pair (50/56 and 52/58) includes a MULCAT (Multi-Layer Coupling Controlled Antenna Technology) coupler for reducing interference between the transmitted and received signals when both antennas are operating. A MULCAT coupler 70 is disposed between 4G LTE/5G antennas 50 and 56 on the right-side surface 42D. Similarly, 4G LTE/5G antennas 52 and 58 on the left-side surface 42C are connected by a MULCAT coupler 72.

Note the decoupling networks 70 and 72 are depicted by simple round circles so as not to complicate FIG. 3. A more detailed discussion and depiction of the decoupling networks is set forth in the co-pending and co-owned application referenced above and bearing application Ser. No. 19/441,019. Additionally, in one embodiment the MULCAT couplers 70 and 72 are disposed in one layer of a printed circuit board. However, in an embodiment requiring extending the length of each MULCAT coupler some of the conductive lines can be overwrapped in multiple layers, that is, one conductive line above, but insulated from, a second conductive line.

The coupling structures 70 and 72 illustrated generally in FIG. 3 can be implemented by various shaped coupling structures, such as described in co-owned application Ser. No. 19/441,019.

Antenna coupling structures are also described in co-owned patent applications/issued patents:
Multilayer Coupling-Controlled Ultra Compact Antenna System; application Ser. No. 18/747,795, filed on Jun. 19, 2024 and now issued U.S. Pat. No. 12,567,674 (Attorney Docket Number 16514-007)
Helical-Shaped Coupling Controlled Compact Antenna System; application Ser. No. 18/747,799, filed on Jun. 19, 2024 (Attorney Docket 16514-009).

Each of the three referenced patent applications are incorporated by reference herein.

Also depicted in FIG. 3, WiFi antennas 60, 62, 64, and 66 are designated for operation according to the WiFi 7 standard within the frequency bands of: 2400-2500 MHz, 5100-5900 MHz, and 5925-7125 MHz.

Antennas 64 and 66 are disposed on the rear surface 42B of the CPE enclosure 42, and antennas 60 and 62 are disposed on the front surface 42A.

Cellular antennas 50 and 52 (see FIG. 3) are capable of 2×2 MIMO operation in the 617-960 frequency range according to the 4G LTE and 5G standards.

Cellular antennas 50, 52, 56, and 58 are capable of 4×4 MIMO operation in the 1447-2690 MHz and 3300-5925 MHz frequency bands according to the 4G LTE and 5G standards.

WiFi antennas 60, 62, 64, and 66 are capable of 4×4 MIMO operation according to the WiFi 7 standard within the frequency bands of 2400-2500 MHz, 5100-5900 MHz, and 5925-7125 MHz.

The operational frequency bands for the several antennas depicted in FIG. 3 are set forth in FIG. 4. The MIMO antenna combinations are also set forth in that Figure.

The 4G LTE/5G antennas are depicted in FIG. 3 as simple rectangles (antennas 50, 52, 54, and 56). But preferably, in one embodiment, the antennas 50 and 56 (and the antennas 52 and 58) comprise dipole antennas, which are known in the art.

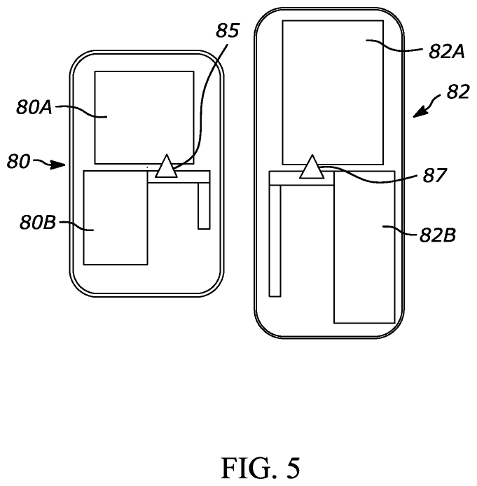

See for example, the dipole antenna 80 and 82 in FIG. 5. The dipole antenna 80 comprises elements 80A and 80B separated by a gap 80C and similarly the dipole antenna 82 comprises elements 82A and 82B separated by a gap 82C. Signal feed points to the antennas are indicated by triangle symbols 85 and 87.

Also, the antennas 50, 52, 56, and 58 are depicted as disposed on two surfaces of the CPE device 42, this is merely exemplary as in another embodiment each one of these antennas can be disposed on only a single surface or multiple surfaces of the CPE device 42.

The described techniques of separating simultaneously operating antennas (in MIMO operation, for example) by a minimum distance to limit interference and/or using decoupling networks as described herein and in the several referenced applications to also limit interference clearly improves antenna performance.

FIG. 3 depicts multiple antennas and decoupling networks designed and located to maximize performance of the CPE device 42. Although the illustrated and described antennas are designated for use in certain frequency bands, are illustrated as having a particular shape, and operating according to certain wireless technologies, those skilled in the art appreciate that other operating frequencies, antenna shapes, and wireless technologies can be accommodated with different antenna designs. The present invention then teaches the design and placement of decoupling networks for use with any such antennas. Additionally, although the antennas are illustrated as simple rectangles to simplify FIG. 3, those skilled in the art understand that various antenna types can be used in the CPE device, such as dipole antennas, patch antennas, meanderline antennas, monopole antennas, and PIFA antennas (planar-inverted F-antennas), among others.

An exemplary system for implementing the invention includes a computing device or a network of computing devices. In a basic configuration, computing device may include any type of stationary computing device or a mobile computing device. Computing device typically includes at least one processing unit and system memory. Depending on the exact configuration and type of computing device, system memory may be volatile (such as RAM), non-volatile (such as ROM, flash memory, and the like) or some combination of the two. System memory typically includes operating system, one or more applications, and may include program data.

Computing device may also have additional features or functionality. For example, computing device may also include additional data storage devices (removable and/or non-removable) such as, for example, magnetic disks, optical disks, or tape. Computer storage media may include volatile and non-volatile, removable and non-removable media implemented in any method or technology for storage of information, such as computer readable instructions, data structures, program modules or other data. System memory, removable storage and non-removable storage are all examples of computer storage media. Computer storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other physical medium which can be used to store the desired information and which can be accessed by computing device. Any such computer storage media may be part of device. Computing device may also have input device(s) such as a keyboard, mouse, pen, voice input device, touch input device, etc. Output device(s) such as a display, speakers, printer, etc. may also be included.

Computing device also contains communication connection(s) that allow the device to communicate with other computing devices, such as over a network or a wireless network. By way of example, and not limitation, communication connection(s) may include wired media such as a wired network or direct-wired connection, and wireless media such as acoustic, RF, infrared and other wireless media.

Computer program code for carrying out operations of the invention described above may be written in a high-level programming language, such as C or C++, for development convenience. In addition, computer program code for carrying out operations of embodiments of the present invention may also be written in other programming languages, such as, but not limited to, interpreted languages. Some modules or routines may be written in assembly language or even micro-code to enhance performance and/or memory usage. It will be further appreciated that the functionality of any or all of the program modules may also be implemented using discrete hardware components, one or more application specific integrated circuits (ASICs), or a programmed digital signal processor or microcontroller. A code in which a program of the present invention is described can be included as a firmware in a RAM, a ROM and a flash memory. Otherwise, the code can be stored in a tangible computer-readable storage medium such as a magnetic tape, a flexible disc, a hard disc, a compact disc, a photo-magnetic disc, a digital versatile disc (DVD). The present invention can be configured for use in a computer or an information processing apparatus which includes a memory, such as a central processing unit (CPU), a RAM and a ROM as well as a storage medium such as a hard disc.

The “step-by-step process” for performing the claimed functions herein is a specific algorithm, and may be shown as a mathematical formula, in the text of the specification as prose, and/or in a flow chart. The instructions of the software program create a special purpose machine for carrying out the particular algorithm. Thus, in any means-plus-function claim herein in which the disclosed structure is a computer, or microprocessor, programmed to carry out an algorithm, the disclosed structure is not the general purpose computer, but rather the special purpose computer programmed to perform the disclosed algorithm.

A general purpose computer, or microprocessor, may be programmed to carry out the algorithm/steps of the present invention creating a new machine. The general purpose computer becomes a special purpose computer once it is programmed to perform particular functions pursuant to instructions from program software of the present invention. The instructions of the software program that carry out the algorithm/steps electrically change the general purpose computer by creating electrical paths within the device. These electrical paths create a special purpose machine for carrying out the particular algorithm/steps.

Unless specifically stated otherwise as apparent from the discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

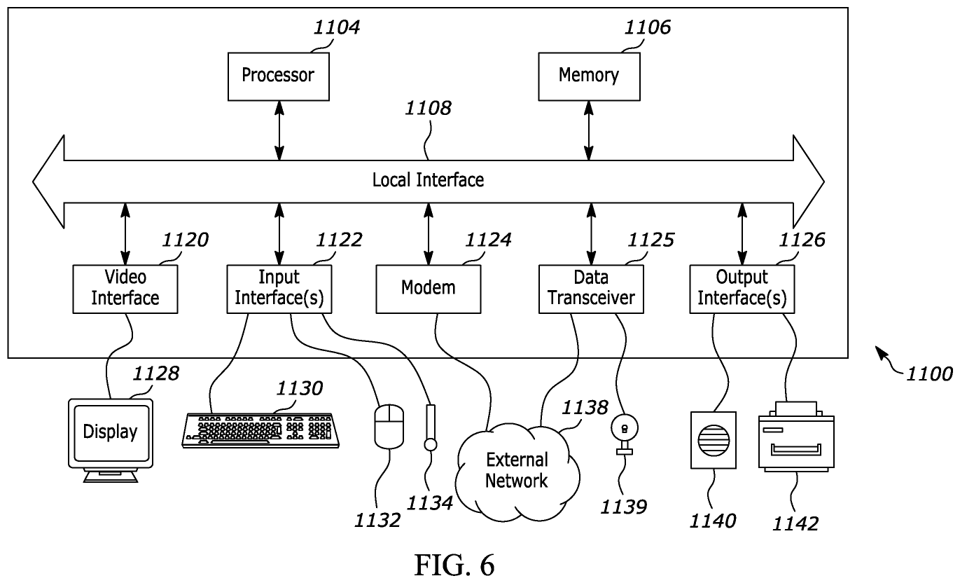

FIG. 6 illustrates a computer system 1100 for use in practicing the invention. The system 1100 can include multiple remotely-located computers and/or processors. The computer system 1100 comprises one or more processors 1104 for executing instructions in the form of computer code to carry out a specified logic routine that implements the teachings of the present invention. The computer system 1100 further comprises a memory 1106 for storing data, software, logic routine instructions, computer programs, files, operating system instructions, and the like, as is well known in the art. The memory 1106 can comprise several devices, for example, volatile and non-volatile memory components further comprising a random access memory RAM, a read only memory ROM, hard disks, floppy disks, compact disks including, but not limited to, CD-ROM, DVD-ROM, and CD-RW, tapes, flash drives and/or other memory components. The system 100 further comprises associated drives and players for these memory types.

In a multiple computer embodiment, the processor 1104 comprises multiple processors on one or more computer systems linked locally or remotely. According to one embodiment, various tasks associated with the present invention may be segregated so that different tasks can be executed by different computers located locally or remotely from each other.

The processor 1104 and the memory 1106 are coupled to a local interface or bus 1108. The local interface 108 comprises, for example, a data bus with an accompanying control bus, or a network between a processor and/or processors and/or memory or memories. In various embodiments, the computer system 1100 further comprises a video interface 1120, one or more input interfaces 1122, a modem 1124 and/or a data transceiver interface device 1125.

The computer system 1100 further comprises an output interface 1126. The system 1100 further comprises a display 1128. The graphical user interface referred to above may be presented on the display 1128. The system 1100 may further comprise several input devices (not shown) including, but not limited to, a keyboard 1130, a mouse 1132, a microphone 1134, a digital camera and a scanner (the latter two not shown). The data transceiver 1125 interfaces with a hard disk drive 1139 where software programs, including software instructions for implementing the present invention are stored.

The modem 1124 and/or data transceiver 1125 can be coupled to an external network 1138 enabling the computer system 1100 to send and receive data signals, voice signals, video signals and the like via the external network 1138 as is well known in the art.

The system 1100 also comprises output devices coupled to the output interface 1126, such as an audio speaker 1140, a printer 1142, and the like.

While the invention has been described with reference to various embodiments, it will be understood by those skilled in the art that various changes may be made and equivalent elements and process steps may be substituted for elements thereof without departing from the scope of the present invention. The scope of the present invention further includes any combination of the elements and process steps from the various embodiments set forth herein. In addition, modifications may be made to adapt a particular situation to the teachings of the present invention without departing from its essential scope. Therefore, it is intended that the invention not be limited to the particular embodiment disclosed as the best mode contemplated for carrying out this invention, but that the invention will include all embodiments falling within the scope of the appended claims.

What is claimed is

1. A method for designing a communications device comprising an antenna system to achieve a predetermined radiation performance, the method comprising:
identifying a frequency, a frequency band, or a plurality of frequency bands in which the communications device is to operate;
determining a number of antennas within the antenna system to achieve the predetermined radiation performance;
determining a physical placement for each antenna within the antenna system relative to physical placement of other antennas within the antenna system;
designing antenna elements for each antenna of the antenna system;
after a step of designing, testing the antenna system relative to the predetermined radiation performance and if the predetermined radiation performance is not achieved, modifying one or more of the antenna elements;
after a step of modifying, first retesting of the antenna system relative to the predetermined radiation performance and if the predetermined radiation performance is achieved, designing an enclosure for the antenna system and incorporating the antenna system into the enclosure, and if the predetermined radiation performance is not achieved returning to a step of modifying; and
after incorporating the antenna system within the enclosure, second retesting of the antenna system relative to the predetermined radiation performance, if the predetermined radiation performance is achieved the method for designing the communications device is concluded, and if the predetermined radiation performance is not achieved modifying one or more elements of the enclosure and re-executing a step of second retesting.

2. The method for designing the communications device of claim 1, wherein the one or more elements of the enclosure comprise, dielectric loading of the enclosure on the antenna system, a material of the enclosure, a thickness of the enclosure, and a distance between antenna elements and the enclosure.

3. The method for designing the communications device of claim 1, wherein the antenna system comprises one or more antennas.

4. The method for designing the communications device of claim 1, wherein the antenna elements comprise a radiating element, and wherein the radiating element comprises one or more of a monopole, a dipole, a planar conductive patch disposed on a dielectric substrate, and a fractal geometry configured to support multiband operation.

5. The method for designing the communications device of claim 4, wherein the dielectric substrate comprises a flexible polymer material.

6. The method for designing the communications device of claim 1, wherein the antenna elements comprise a feed structure, and wherein the feed structure comprises at least one of, a coaxial probe feed, a microstrip line feed, or a coplanar waveguide feed.

7. The method for designing the communications device of claim 1, wherein the communications device is configured to operate within at least one of 617 to 960 MHz, 1447 to 2690 MHz, 3300 to 5925 MHz, 5100 to 5900 MHz, and 5925 to 7125 MHz.

8. The method for designing the communications device of claim 1, wherein the communications device is configured to support one or more of 2×2 MIMO operation at 617 to 960 MHz, 4×4 MIMO operation at 1447 to 2690 MHz, 4×4 MIMO operation at 3300 to 5925 MHz, 4×4 MIMO operation at 2400 to 2500 MHz, 4×4 MIMO operation at 5100 to 5900 MHz, and 4×4 MIMO operation at 5925 to 7125 MHz.

9. The method for designing the communications device of claim 1, wherein the the antenna elements comprise a radiating element and a ground plane, and wherein the radiating element and the ground plane are integrated into a printed circuit board.

10. The method for designing the communications device of claim 1, wherein the communications device is integrated into a mobile communication device, or is integrated into a WiFi router, or is integrated into a communications device capable of operating at both WiFi frequencies and cellular frequencies, or is integrated into an internet of things (IOT) device.

11. The method for designing the communications device of claim 1, wherein a step of modifying one or more parameters of the housing reduces detuning of the antenna system, improves current redistribution within the antenna system, reduces radiation absorption losses, reduces radiation pattern distortion, reduces near field coupling due to proximate antennas of the antenna system, reduces interaction of the ground plane and the antenna system, and reduces a change in operating frequency or bandwidth.

12. After the method for designing the communications device of claim 1 is concluded, further comprising steps of chipset/component design and selection, PCB design, component layout, cable/conductor design and installation, and development of operating software.

13. After the method for designing the communications device of claim 12 is concluded, further comprising third retesting of the antenna system relative to the predetermined radiation performance. if the predetermined radiation performance is not achieved, modifying one or more elements of the antenna system or of the operating software.

14. The method for designing the communications device of claim 1, wherein the predetermined radiation performance relates to one or more of operating frequency, radiation pattern, bandwidth, gain, impedance, efficiency, and signal polarization.

15. The method for designing the communications device of claim 1, wherein the antenna elements comprise one or more of a number of antennas within the antenna system, a physical location of each antenna, a separation distance between each antenna, a radiating element of each antenna, a ground plane, a feed structure, a coupling element between proximate antennas to reduce negative coupling between the proximate antennas, and a distance between the ground plane and the radiating element.

16. A method for designing a communications device comprising an antenna system to achieve desired performance metrics, the method comprising:
executing each step in a sequence as set forth:
(a) designing and constructing an antenna system;
(b) testing the antenna system relative to the desired performance metrics;
(c) if the desired performance metrics are achieved based on results from step (b), proceeding to step (d), if the desired performance metrics are not achieved based on results from step (b), modifying the antenna system and re-executing step (b);
(d) designing an enclosure for the antenna system;
(e) incorporating the antenna system into the enclosure;
(f) testing the antenna system in the enclosure relative to the desired performance metrics; and
(g) if the desired performance metrics are achieved based on results from step
(f), a design of the communications device comprising an antenna system to achieve desired performance metrics has been completed, if the desired performance metrics are not achieved based on results from step (f), modifying elements of the enclosure and re-executing step (f).

17. The method of claim 16, wherein the antenna system comprises at least two antennas and a coupling element to reduce negative coupling between the at least two antennas.

18. The method of claim 16, wherein the elements of the enclosure comprise, dielectric loading of the enclosure on the antenna system, a material of the enclosure, a thickness of the enclosure, and a distance between antenna elements and the enclosure.

19. The method of claim 16, wherein the antenna system supports one or both of 2×2 MIMO operation and 4×4 MIMO operation.

20. A communications device designed according to the method of claim 16.
